(19) United States
(12) Patent Application Publication
(10) Pub. No.: US 2011/0095419 A1
(43) Pub. Date: Apr. 28, 2011

(54) CONDUCTIVE FILM, METHOD OF MANUFACTURING THE SAME, SEMICONDUCTOR DEVICE AND METHOD OF MANUFACTURING THE SAME

(75) Inventors: Michio Horiuchi, Nagano-shi (JP); Yasue Tokutake, Nagano-shi (JP); Yuichi Matsuda, Nagano-shi (JP); Tsuyoshi Kobayashi, Nagano-shi (JP); Tatsuaki Denda, Nagano-shi (JP)

(73) Assignee: SHINKO ELECTRIC INDUSTRIES CO., LTD., Nagano-shi (JP)

(21) Appl. No.: 12/909,096

(22) Filed: Oct. 21, 2010

(30) Foreign Application Priority Data
Oct. 22, 2009 (JP) 2009-243028

(51) Int. Cl. H01L 23/498; H01L 21/768; H05K 1/11; B05D 5/12

(52) U.S. Cl. 257/737; 438/121; 174/262; 427/97.8; 257/E23.068; 257/E21.575

(57) ABSTRACT

There is provided a conductive film. The conductive film includes: an anodized layer having a plurality of through holes extending therethrough in its thickness direction; a plurality of linear conductors each formed in a corresponding one of the through holes and each having first and second protrusions protruding from the anodized layer, wherein at least one of the first and second protrusions is covered by a coating material; and an uncured thermosetting resin layer formed on the anodized layer to cover at least one of the first and second protrusions.

This application claims priority from Japanese Patent Application No. 2009-243028, filed on Oct. 22, 2009, the entire contents of which are herein incorporated by reference.

### BACKGROUND

1. Technical Field

The present disclosure relates to a conductive film, a method of manufacturing the same, a semiconductor device and a method of manufacturing the same.

2. Related Art

For a connecting structure of a semiconductor device, JP-A-9-293759 discloses a technique using an uncured resin as a connecting member.

JP-A-2000-223534 discloses a technique using a resin layer made of an anisotropically conductive paste as a connecting member.

JP-A-2003-31617 discloses a technique using a mixture of conductive particles and a synthetic resin as a connecting member.

JP-A-10-308565 and JP-A-9-331134 disclose a wiring board in which metal wires are buried within a fired columnar porous body made of an inorganic insulation material in parallel with an axis of the columnar body.

JP-A-10-189096 discloses a board bonding film having a resin material and conductive portions formed by filling a metal in connecting holes penetrating through the resin material in its thickness direction, wherein the resin material has an electric insulation property and an adhesiveness through a heating process.

According to the disclosure of the above mentioned documents, it is considered that it is possible to manufacture a semiconductor device in which electronic components (e.g., semiconductor elements) are mounted on the wiring board. Since the wiring board in the packaging structure is used to mount electronic components including the semiconductor element, it is called a semiconductor package, or simply, a package. In addition, in the present embodiment, a structure including the semiconductor element is referred to as a semiconductor device.

As the connecting member in the case of packaging, for example, an anisotropic conductive film (ACF) is used in which conductive balls having a size of several micrometers are diffused in a thermosetting resin. By providing an anisotropic conductive film having conductive balls therein between the wiring board and the semiconductor element and heating and pressing them, the thermosetting resin is fluidized, and the conductive balls are inserted between the connecting terminal of the wiring board and the connecting terminal of the semiconductor element, so that the wiring board and the semiconductor element are electrically connected to each other.

However, as semiconductor devices are miniaturized and high-functioned, a connecting terminal of the semiconductor element becomes finer in size and narrower in pitch (finer pitch). In this manner, if the semiconductor element having a connecting terminal having a finer size and a narrower pitch is packaged on the wiring board using the anisotropic conductive film having the conductive balls, the conductive balls are pressed and extracted from the space between the connecting terminal of the semiconductor element and the connecting terminal of the wiring board that are facing each other and make contact with the neighboring connecting terminal, so that an electrical short may occur between the connecting terminals. Therefore, in the semiconductor device in which a plurality of components are connected (e.g., packaged), a connection reliability and a product yield may be degraded.

It is envisaged that such a problem in the connecting terminals is influenced by the sizes of the connecting terminal and the conductive ball, flatness or thermal expansion of the anisotropic conductive film during the packaging. Through diligent study, the inventors discovered that, when an anisotropic conductive film having typical conductive balls is used in the semiconductor element having a connecting terminal in an area array state, and the pitch between the connecting terminals is equal to or smaller than 0.1 mm, appropriate connection is difficult.

### SUMMARY OF THE INVENTION

Exemplary embodiments of the present invention address the above disadvantages and other disadvantages not described above. However, the present invention is not required to overcome the disadvantages described above, and thus, an exemplary embodiment of the present invention may not overcome any disadvantages described above.

According to one or more aspects of the invention, there is provided a conductive film. The conductive film includes: an anodized layer having a plurality of through holes extending therethrough in its thickness direction; a plurality of linear conductors each formed in a corresponding one of the through holes and each having first and second protrusions protruding from the anodized layer, wherein at least one of the first and second protrusions is covered by a coating material; and an uncured thermosetting resin layer formed on the anodized layer to cover at least one of the first and second protrusions.

Other aspects and advantages of the present invention will be apparent from the following description, the drawings and the claims.

### BRIEF DESCRIPTION OF THE DRAWINGS

FIG. 1 is a cross-sectional view schematically illustrating a conductive film during a manufacturing process according to an embodiment of the present invention;

FIG. 2 is a cross-sectional view schematically illustrating a conductive film during a manufacturing process subsequent to FIG. 1;

FIG. 3 is a cross-sectional view schematically illustrating a conductive film during a manufacturing process subsequent to FIG. 2;

FIG. 4 is an enlarged cross-sectional view schematically illustrating a main part of the conductive film shown in FIG. 3;

FIG. 5 is a cross-sectional view schematically illustrating a conductive film during a manufacturing process subsequent to FIG. 4;

FIG. 6 is a SEM image illustrating surface morphology of an anodized layer having a plurality of through holes therein;

FIG. 7 is a SEM image illustrating surface morphology of an anodized layer having a plurality of linear conductors therein;

FIG. 8 is a cross-sectional view schematically illustrating a semiconductor device during a manufacturing process according to an embodiment of the present invention;

FIG. 9 is a cross-sectional view schematically illustrating a semiconductor device during a manufacturing process subsequent to FIG. 8;

FIG. 10 is an enlarged cross-sectional view schematically illustrating a main part (in other words, protrusions 3a of linear conductors 3 which are to be connected to connecting terminals 21) of the semiconductor device shown in FIG. 9;

FIG. 11 is an enlarged cross-sectional view schematically illustrating a main part (in other words, protrusions 3a of linear conductors 3 which are to be connected to connecting terminals 31) of the semiconductor device shown in FIG. 9;

FIG. 12 is a cross-sectional view schematically illustrating a conductive film during a manufacturing process according to another embodiment of the present invention; and

FIG. 13 is a cross-sectional view schematically illustrating a semiconductor device during a manufacturing process according to still another embodiment of the present invention.

### DETAILED DESCRIPTION OF EXEMPLARY EMBODIMENTS

Hereinafter, exemplary embodiments of the present invention will be described with reference to the accompanying drawings. In all the drawings for the explanation of the embodiments, the members having the same functions are represented by the same reference numerals, and repeated description thereof will be omitted.

### First Embodiment

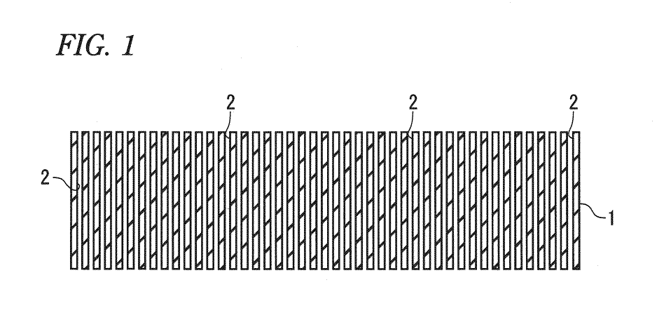

A method of manufacturing a conductive film according to the present embodiment will be now described. First of all, as shown in FIG. 1, an anodized layer 1 having a plurality of through holes 2 extending therethrough in the thickness direction is prepared. When aluminum (Al) is used as the metal, aluminum oxide which is an inorganic insulation layer is formed as the anodized layer 1 by anodizing aluminum.

For example, firstly, an aluminum plate having a size of 10 mm×10 mm, of which one surface is insulated with a film is prepared, and the surface of the aluminum plate is cleaned. Then, the aluminum plate is used as the positive electrode by immersing it in an electrolyte liquid such as an aqueous solution of a sulfuric acid or an oxalic acid, and an electric current flows (by applying a pulse voltage) through a platinum (Pd) plate arranged to face the aluminum plate as a negative electrode, so that a porous layer (the holes 2) can be formed on the surface of the aluminum plate. Then, the porous layer is separated from the remaining aluminum plate, for example, through cutting to form the through holes in the porous layer. As a result, it is possible to obtain an anodized layer 1 having multiple pores extending therethrough in the thickness direction, i.e., a plurality of fine through holes 2.

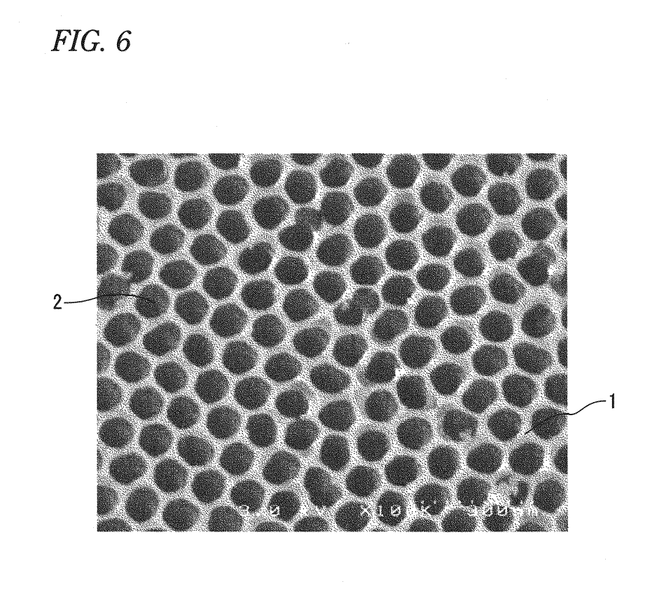

FIG. 6 is a SEM image illustrating surface morphology of the anodized layer 1 where a plurality of through holes 2 are provided. As shown in FIG. 6, it can be seen that pores having a honeycomb structure are formed on the surface of the anodized layer 1 through self-organization.

In the anodizing of aluminum, the aluminum oxide layer is formed by electrochemically oxidizing the surface of aluminum. In the anodizing, it is possible to adjust the thickness of the anodized layer 1 or a diameter or a pitch of the through holes 2 depending on conditions such as the type of the electrolyte liquid, voltage, and time. Here, the pitch of the through holes 2 is defined as a distance between centers of the adjacent through holes. For example, the thickness (the depth of the through holes 2) of the anodized layer 1 may be set to about 70 μm to about 180 μm, the diameter of the through hole 2 may be set to about 30 nm to about 1000 nm, and the pitch of the through hole 2 may be set to about 40 nm to about 1200 nm. In this manner, the aspect ratio (a ratio between the depth and the diameter of hole) of the through holes 2 in the anodized layer 1 is set to be high.

Through the aforementioned process, the anodized layer 1 where a plurality of through holes 2 are densely arranged in parallel with the thickness direction is formed within a plane having a size of approximately 10 mm×10 mm.

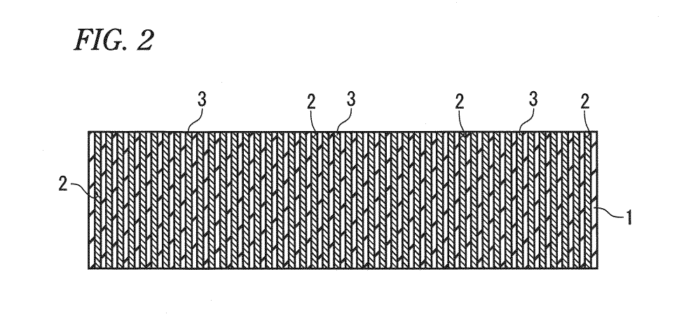

Subsequently, as shown in FIG. 2, a plurality of linear conductors 3 are formed by filling each of the through holes 2 with a conductive material. Then, the surface of the anodized layer 1 is polished to obtain flatness of the surface of the anodized layer 1 or uniformity of the length of the linear conductor 3.

For example, the fine through holes 2 may be filled with a conductive material using an electrolytic plating in which an electrode is provided on one surface of the anodized layer 1. Thus, the linear conductor 3 is made of such a conductive material. As a conductive material, copper (Cu), nickel (Ni) may be used in consideration of electric conductivity, corrosion resistance, or the like. As a result, it is possible to form the anodized layer 1 having a plurality of linear conductors 3 extending therethrough in the thickness direction. In addition, in order to improve the anti-corrosion property of the anodized layer 1, the internal side of the through holes 2 is covered by a barrier film, and a conductive material such as copper may be filled therein.

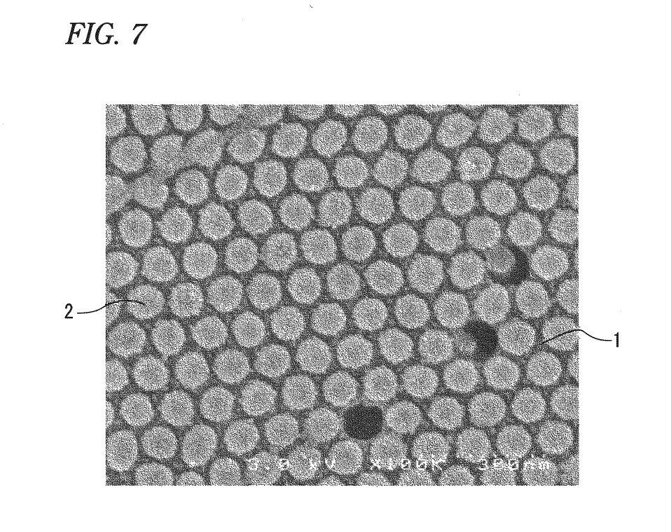

FIG. 7 is a SEM image illustrating surface morphology of the anodized layer 1 where a plurality of linear conductors 3 are provided. The through hole 2 of the linear conductor 3 is filled with a conductive material, and, for example, the linear conductor 3 may have a length of 70 to 180 μm, a diameter of 30 to 1000 nm, and a pitch equal to or higher than 40 nm and equal to or less than 1200 nm. That is, such a fine linear conductor 3 can be formed by filling the through hole 2 of the anodized layer 1 with a conductive material.

Through the aforementioned process, an anodized layer 1 is formed, in which a plurality of linear conductors 3 are densely arranged in parallel with the thickness direction on a plane having a size of approximately 10 mm×10 mm. That is, a plurality of linear conductors 3 are densely arranged in the anodized layer 1 in parallel with one another with an interval smaller than a diameter thereof.

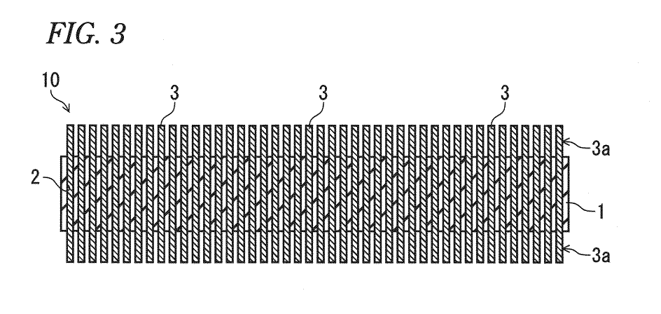

Subsequently, as shown in FIG. 3, a part of the anodized layer 1 is removed in the thickness direction from the surface of the anodized layer 1, and both ends of the linear conductors 3 protrude from the anodized layer 1. For example, it is possible to expose both ends of the linear conductor 3 by immersing the anodized layer 1 in a sodium hydroxide aqueous solution at a temperature of 50° C. to 60° C. to etch the anodized layer 1 from both surfaces thereof.

Generally, it is known that crystals of an aluminum oxide obtained by anodizing aluminum are called alumina Al₂O₃. Alumina has excellent durability and is highly resistant to acids or alkalis. However, the anodized layer 1 of the present embodiment is not perfect alumina, but the aluminum oxide is a boehmite. Therefore, the anodized layer 1 is vulnerable to alkalis, and the surface of the anodized layer 1 can be easily etched using sodium hydroxide. In addition, since a boehmite (the anodized layer 1) is not harder than alumina, it is useful from the viewpoint of flexibility when it is used as a film.

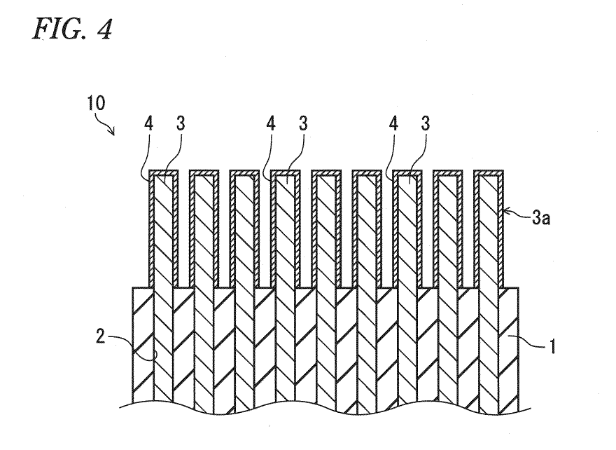

Then, as shown in FIG. 4, a coating material 4 is attached to the protrusions 3a (on both ends) of a plurality of the protruding (exposed) linear conductors 3. As a result, a conductor film 10 is provided. In FIG. 3, while the coating material 4 is attached to both ends of the linear conductors 3, they are not shown.

In the present embodiment, tin or low melting-point alloy containing tin attached through a pre-soldering process is used as the coating material 4. If the conductive coating material 4 such as tin or low melting-point alloy containing tin is formed on the anodized layer 1, a gap between the linear conductors 3 may be shorted (bridged). In such a case, a manufacturing yield of the conductive film is degraded. In this regard, it is possible to attach the coating material 4 to the end of the linear conductor 3 by substituting the surface of the protrusion 3a of the linear conductor 3, for example, with a coating material such as tin through displacement plating. In this manner, the coating material 4 is not attached to the anodized layer 1, but only attached to the protrusion 3a of the linear conductor 3 protruding from the anodized layer 1.

In addition, an anti-corrosion treatment may be applied to the coating material 4, for example, using a fatty acid, an aliphatic hydrocarbon-based lubricant, a metal soap-based lubricant, a fatty acid ester-based lubricant, or the like. As a result, it is possible to prevent the exposed linear conductor 4 from being oxidized as time goes by.

The conductive film 10 includes an anodized layer 1 having a plurality of through holes 2 extending therethrough in the thickness direction and a plurality of linear conductors 3, each of which is formed on the corresponding through hole 2 and has a protrusion 3a protruding from the anodized layer 1, and the coating material 4 is attached to the protrusion 3a.

The conductive film 10 can be referred to as an anisotropic conductive film because a plurality of the linear conductors 3 are electrically insulated from one another in the thickness direction, and they are anisotropic in the current-flowing direction. In the conductive film 10, the fine linear conductor 3 is formed by filling the through hole 2 of the anodized layer 1 with a conductive material as described above, and thus the conductive film 10 can be used to connect the wiring board to a semiconductor element having a narrow pitch connecting terminal.

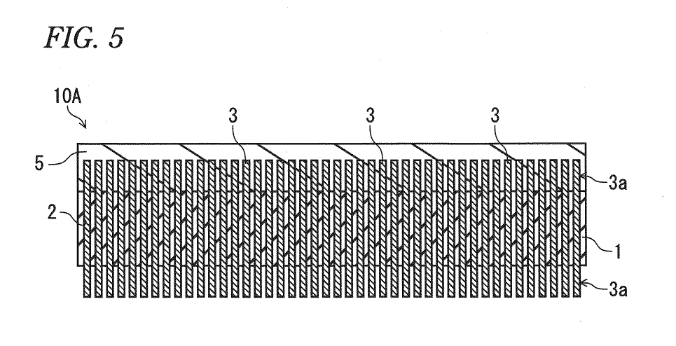

Subsequently, as shown in FIG. 5, an organic insulation layer 5 is formed on one surface of the anodized layer 1 such that the gaps between the protruding linear conductors 3 are filled with the organic insulation layer 5. As a result, it is possible to form a conductive film 10A having the organic insulation layer 5 on one surface of the anodized layer 1 from the conductive film 10. In addition, it is possible to protect the linear conductors 3 using the organic insulation layer 5.

In the present embodiment, the organic insulation layer 5 is made of uncured thermosetting resin. For example, it is possible to form the organic insulation layer 5 by coating filler-free epoxy resin (thermosetting resin) on one surface of the anodized layer 1 to fill the gaps between the linear conductors 3 having a narrow pitch.

In this manner, the conductive film 10A includes the organic insulation layer 5, which is an uncured thermosetting resin layer formed on the anodized layer 1, by filling the gaps between the protrusions 3a of a plurality of linear conductors 3. In case where the organic insulation layer 5 is the uncured thermosetting resin layer, it is possible to obtain higher flexibility than that of the cured thermosetting resin layer.

In addition, in the present embodiment, as shown in FIG. 5, the uncured thermosetting resin layer (the organic insulation layer 5) fills the gaps between the protruding linear conductors 3 and covers the linear conductors 3. Therefore, the linear conductors 3 are not exposed from the organic insulation layer 15. However, since the organic insulation layer 5 includes an uncured thermosetting resin layer, when the linear conductor 3 is connected to, for example, the connecting terminal of the semiconductor element, the thermosetting resin floats by heating the organic insulation layer 5, so that the linear conductor 3 can make contact with the connecting terminal.

As described above, while the anodized layer 1 (the inorganic insulation layer) as a core layer of the conductive film 10A is a boehmite, the organic insulation layer 5 having lower elastic modulus than that of the anodized layer 1 is formed on the anodized layer 1 in order to obtain flexibility as a film. That is, it is possible to distribute stress during the connection by introducing the organic insulation layer 5 having a low elastic modulus in the conductive film 10A.

In addition, since the anodized layer 1 is an aluminum oxide in a boehmite state, durability is worse than alumina. However, in the present embodiment, since the organic insulation layer 5 is formed on the anodized layer 1, it is possible to guarantee durability of the conductive film 10A.

While, in the conductive film 10A, the organic insulation layer 5 is formed on one surface of the anodized layer 1, the organic insulation layer 5 may be formed on both surfaces of the anodized layer 1. If the organic insulation layer 5 is provided on both surfaces of the anodized layer 1, it is possible to further improve flexibility, durability, and stress distribution during connection as compared with the case where the organic insulation layer 5 is provided on one surface.

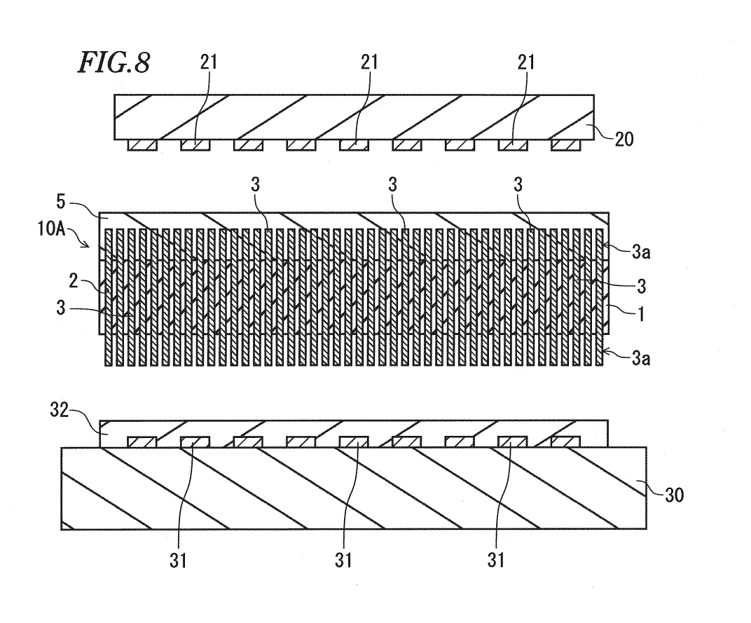

Next, a method of manufacturing the semiconductor device using the conductive film 10A according to the present embodiment will be now described. As shown in FIG. 8, a semiconductor element (chip) 20 having connecting terminals 21 thereon, an wiring board 30 (component) having connecting terminals 31 thereon, and a conductive film 10A are prepared.

The semiconductor element 20 is formed through a known manufacturing technique. In the semiconductor element 20, for example, an element formation surface (main surface) side where an MIS (Metal Insulator Semiconductor) transistor is formed is covered with a passivation film, and the connecting terminals 21 as external connecting terminals are arranged in an area array shape having a pitch equal to or smaller than 100 μm, for example. In addition, in the wiring board 30, the main body is made of a resin, and the outermost surface of a multi-layered structure, for example, formed using a build-up technique is covered by a solder resist layer, and the connecting terminals 31 as external connecting terminals are arranged in an area array shape.

Then, the semiconductor element 20 and the wiring board 30 are electrically and mechanically connected to each other by interposing the conductive film 10A therebetween. In this case, an uncured thermosetting resin layer (e.g., an epoxy resin layer) as the organic insulation layer 32 is formed on the wiring board 30 to cover the connecting terminals 31.

In the conductive film 10A according to the present embodiment, a plurality of linear conductors 3 are densely arranged in parallel with one another in the thickness direction within a plane having a size of 10 mm×10 mm. Accordingly, at the time of positioning for packaging, it is not necessary to know in advance which linear conductor 3 is connected to the connecting terminals 21 and the connecting terminals 31.

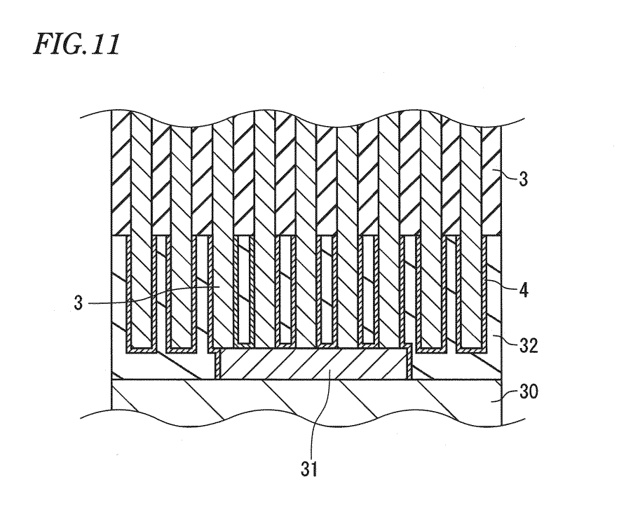

Then, the semiconductor element 20 having the connecting terminals 21 thereon is disposed on the anodized layer 1, and the anodized layer 1 is heated and pressed so that the linear conductors 3 and the connecting terminal 21 are bonded using the coating material 4 while they make contact with each other, and the thermosetting resin layer (the organic insulation layer 5) is cured. Also, the wiring board 30 having the connecting terminals 31 thereon is arranged on the anodized layer 1, and they are heated and pressed so that the linear conductors 3 and the connecting terminals 31 are bonded using a coating material 4 (see FIG. 11) while they make contact with each other, and the thermosetting resin layer (the organic insulation layer 32) is cured. Thus, as shown in FIG. 11, the protrusions 3 are connected to the connecting terminals 31 via the coating material 4.

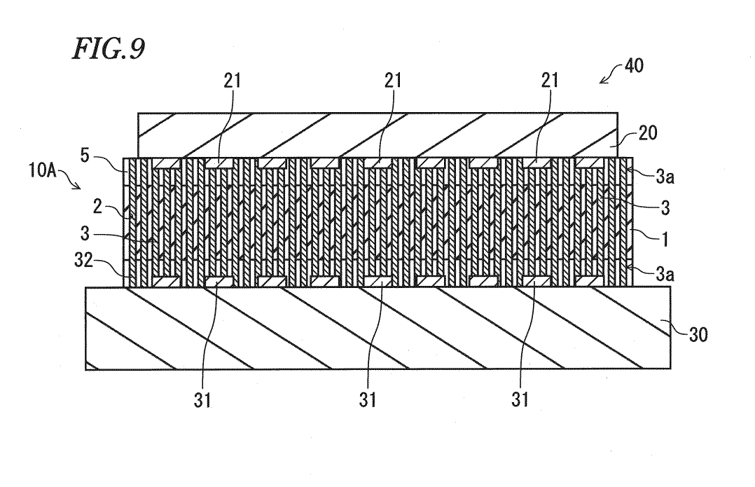

For example, the semiconductor element 20, the conductive film 10A, and the wiring board 30 are overlapped with each other between a pair of press heating plates, and they are heated and pressed from both the upper and lower faces using a vacuum press, so that it is possible to roughly complete the semiconductor device 40 having an integrated structure as shown in FIG. 9.

Through such a heating and pressing process, the uncured thermosetting resin layer (the organic resin layers 5 and 32) arranged on both surfaces of the conductive film 10A is melted, and the melted resin fills the gap between the semiconductor element 20 and the wiring board 30 as an underfill resin layer. In addition, the thermosetting resin layer (the organic resin layers 5 and 32) between the semiconductor element 20 and the conductive film 10A and between the wiring board 30 and the conductive film 10A fills the gaps between the protrusions 3a of the linear conductors 3. Therefore, if such a thermosetting resin layer (the organic resin layers 5 and 32) is thermally cured, mechanical bonding is obtained between the conductive film 10A, the semiconductor element 20, and the wiring board 30.

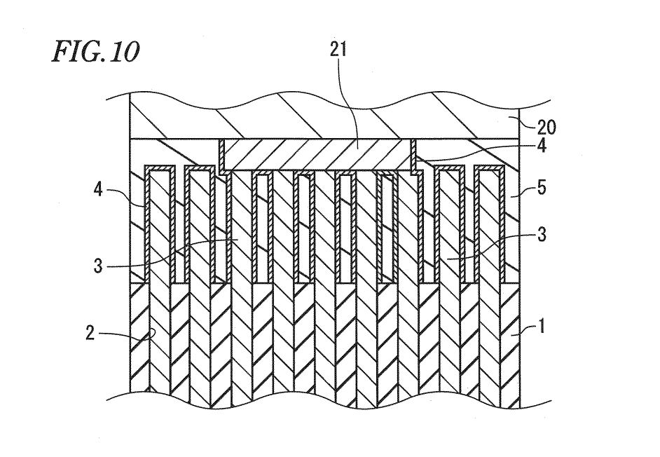

In addition, in the course of the heating and pressing process, as shown in FIG. 10, a bundle of linear conductors 3 among a plurality of linear conductors 3 of the conductive film 10A make contact with the connecting terminals 21 of the semiconductor element 20 at the protrusion 3a so that they are electrically connected to each other. Similarly, a bundle of linear conductors 3 among a plurality of linear conductors 3 of the conductive film 10A make contact with the connecting terminals 31 of the wiring board 30 at the protrusion 3a so that they are electrically connected to each other. In this case, due to a volume contractibility of the thermally cured thermosetting resin layer (the organic resin layers 5 and 32), a contact condition between the connecting terminals 21, 31 and the linear conductor 3 is fixed by the thermosetting resin layer. Therefore, an electric connection between the conductive film 10A, the semiconductor element 20, and the wiring board 30 is stably maintained.

In addition, since the coating material 4 made of tin or a low-melting point metal containing tin is attached to the protrusion 3a of the linear conductor 3 through a pre-solder process, the coating material 4 is melted in the course of the heating and pressing process so that one ends of the linear conductors 3 are bonded to the connecting terminals 21 of the semiconductor element 20 as shown in FIG. 10. Similarly, the coating material 4 is melted so that the other ends of the linear conductor 3 are bonded to the connecting terminal 31 of the wiring board 30. Therefore, electric connection between the conductive film 10A, the semiconductor element 20, and the wiring board 30 is more stably maintained.

In this manner, if the conductive film 10A (the conductive film 10) according to the present embodiment is included, it is possible to improve connection reliability and provide a semiconductor device 40 having an improved manufacturing yield.

The present invention is not limited to the above-mentioned embodiment. For example, referring to FIGS. 8 to 11, the coating materials 4 may be coated on any one of the protrusions 3a (hereinafter, referred to as first protrusions), which are covered by the organic resin layer 5, and the protrusions 3a (hereinafter, referred as to second protrusions), which are exposed from the outside.

Furthermore, in the conductive film 10A shown in FIG. 8, the first protrusions 3a are covered by the organic resin layer 5, while the second protrusions 3a are exposed from the outside (i.e., not covered by the organic resin layer 32). However, the present invention is not limited thereto. For example, in the conductive film 10A shown in FIG. 8, both of the first and second protrusions 3a may be covered by the organic resin layers 5 and 32, respectively.

### Second Embodiment

A method of manufacturing a conductive film according to another embodiment of the present invention will be now described. Firstly, the conductive film 10 is formed through the processes shown in FIGS. 1 to 4 as described in the first embodiment. That is, the conductive film 10 includes the anodized layer 1 having a plurality of linear conductors 3 in parallel in the thickness direction within a plane having a size of 10 mm×10 mm. The linear conductors 3 have a length of 70 μm to 180 μm, a diameter of 30 nm to 1000 nm, and a pitch equal to or higher than 40 nm and equal to or less than 1200 nm. In this manner, in the conductive film 10, a plurality of linear conductors 3 are densely arranged in parallel with one another with a gap smaller than the diameter thereof within the anodized layer 1.

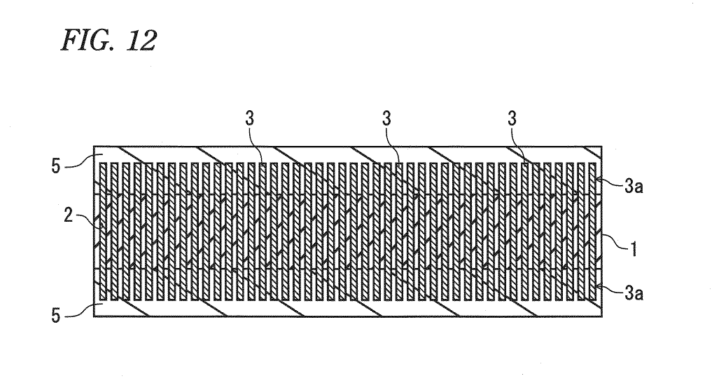

Subsequently, the organic insulation layer 5 is formed on both surfaces of the anodized layer 1, which is an inorganic insulation layer, to fill the gaps between a plurality of the protruding linear conductors 3 (see FIG. 12). In this case, the organic resin layer 5 is formed to cover the linear conductors 3.

In the present embodiment, the organic insulation layer 5 is made of uncured thermosetting resin. For example, the organic insulation layer 5 can be formed by coating the filler-free epoxy resin (thermosetting resin) on one surface of the anodized layer 1 in order to fill the gaps between the linear conductors 3 having a narrow pitch.

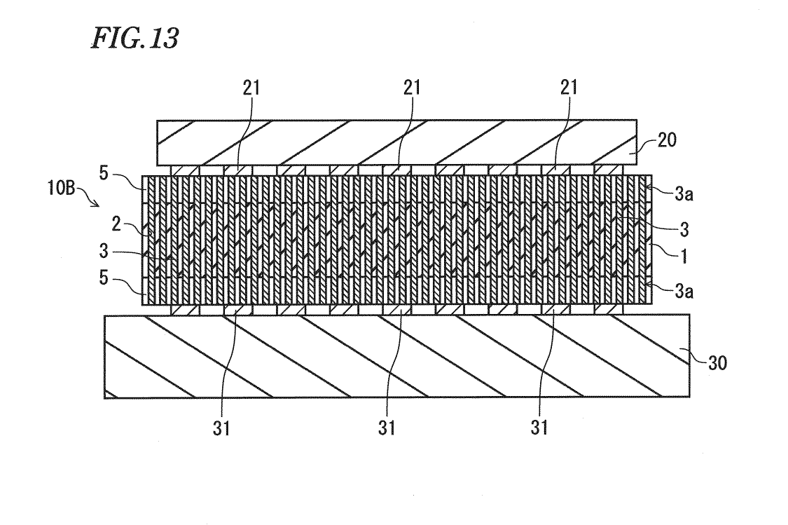

Subsequently, the uncured thermosetting resin layer (the organic resin layer 5) is melted by heating and thermally cured. Then, a part of the organic resin layer 5 is removed in the thickness direction from the surface of the organic resin layer 5, and the surfaces of the linear conductors 3 are exposed from the surface of the organic resin layer 5. As a result, it is possible to form the conductive film 10B including the anodized layer 1 (an inorganic insulation layer) where a plurality of linear conductors 3 extend in the thickness direction and the organic resin layer 5 provided on both surfaces of the anodized layer 1, wherein the surfaces of the linear conductors 3 are exposed through the organic resin layer 5 (see FIG. 13).

Here, in the present embodiment, the elastic modulus of the organic insulation layer 5 of the conductive film 10B is lower than that of the anodized layer 1 which is an inorganic insulation layer, and equal to or higher than 1 Pa and equal to or lower than 10 MPa. In addition, while the thermosetting resin layer (epoxy resin) is used as the organic insulation layer 5 in such a condition, silicon rubber may be used.

Such a conductive film 10B may be used as a connecting member which is repeatedly used during an electrical characteristic testing process in the manufacturing process of the semiconductor element 20 (the semiconductor device) having connecting terminals with a narrow pitch.

The semiconductor element 20 is formed through a known manufacturing technique. In the semiconductor element 20, for example, an element formation surface (main surface) side where an MIS (Metal Insulator Semiconductor) transistor is formed is covered with a passivation film, and the connecting terminal 21 as external connecting terminals is arranged in an area array shape (for example, a pitch is equal to or smaller than 100 μm).

In the final process of the semiconductor element 10, an electrical characteristic test is performed for the semiconductor element 20 having connecting terminals 21 with a narrow pitch by providing the conductive film 10B on the wiring board 30 as shown in FIG. 12. Here, if the conductive film 10B according to the present embodiment is used, it is possible to perform the electric characteristic test even when the semiconductor element 20 has connecting terminals 21 having a narrow pitch, for example, equal to or smaller than 100 μm.

While the present invention has been shown and described with reference to certain exemplary embodiments thereof, other implementations are within the scope of the claims. It will be understood by those skilled in the art that various changes in form and details may be made therein without departing from the spirit and scope of the invention as defined by the appended claims.

For example, in the first embodiment, while the surface of the anodized layer 1 is etched in the process shown in FIG. 3, it may be used as the conductive film without etching if connectivity to the exposed surface can be obtained in the case where the linear conductor 3 is exposed from the surface of the anodized layer 1.

What is claimed is:

1. A conductive film comprising:
an anodized layer having a plurality of through holes extending therethrough in its thickness direction;
a plurality of linear conductors each formed in a corresponding one of the through holes and each having first and second protrusions protruding from the anodized layer, wherein at least one of the first and second protrusions is covered by a coating material; and
an uncured thermosetting resin layer formed on the anodized layer to cover at least one of the first and second protrusions.

2. The conductive film according to claim 1, wherein the coating material is made of tin or an alloy containing tin.

3. The conductive film according to claim 1, wherein the thermosetting resin layer is a filler-free epoxy resin.

4. The conductive film according to claim 1, wherein the anodized layer is boehmite.

5. A conductive film comprising:
an inorganic insulation layer;
organic insulation layers formed on both surfaces of the inorganic insulation layer; and
a plurality of linear conductors extending through the inorganic insulation layer and the respective organic insulation layers in their thickness direction to be exposed from surfaces of the respective organic insulation layers,
wherein the inorganic insulation layer is an anodized layer having a plurality of through holes extending therethrough in its thickness direction, and each of the linear conductors is formed in a corresponding one of the through holes.

6. The conductive film according to claim 5, wherein an elastic modulus of the organic insulation layer is in a range of about 1 Pa to about 10 MPa.

7. A method of manufacturing a conductive film, the method comprising:
(a) providing an anodized layer having a plurality of thorough holes extending therethrough in its thickness direction;
(b) forming a plurality of linear conductors by filling each of the through holes with a conductive material;
(c) removing a part of the anodized layer from the thickness direction of the anodized layer, so that each of the linear conductors has first and second protrusions protruding from the anodized layer;
(d) covering at least one of the first and second protrusions with a coating material; and
(e) forming an organic insulation layer on the anodized layer to cover at least one of the first and second protrusions.

8. A semiconductor device comprising:
a semiconductor element having first connecting terminals thereon;
an electrical component having second connecting terminals thereon; and
a conductive film disposed between the semiconductor element and the electrical component to electrically connect the first connecting terminals to the second connecting terminals, the conductive film comprising:
an anodized layer having a plurality of through holes extending therethrough in its thickness direction;
a plurality of linear conductors each formed in a corresponding one of the through holes and each having first and second protrusions protruding from the anodized layer, and
wherein the first connecting terminals are in contact with the first protrusions, and the second connecting terminals are in contact with the second protrusions, and
wherein the first and second connecting terminals are electrically connected to each other.

9. The semiconductor device according to claim 8, wherein at least one of the first and second protrusions is covered by a coating material, and the coating material is made of tin or an alloy containing tin.

10. The semiconductor device according to claim 8, further comprising:
a thermosetting resin formed between the semiconductor element and the conductive film and between the electrical component and the conductive film such that the first and second protrusions are embedded in the thermosetting resin.

11. A method of manufacturing a semiconductor device, comprising:
(a) providing an anodized layer having a plurality of through holes extending therethrough in its thickness direction;
(b) forming a plurality of linear conductors by filling each of the through holes with a conductive material;
(c) removing a part of the anodized layer from the thickness direction of the anodized layer, so that each of the linear conductors has first and second protrusions protruding from the anodized layer;
(d) covering at least one of the first and second protrusions with a coating material;
(e) forming an uncured thermosetting resin layer on the anodized layer to cover at least one of the first and second protrusions, thereby forming a conductive film comprising the thermosetting resin layer and the linear conductors; and
(f) providing a semiconductor element having connection terminals thereon
(g) disposing the semiconductor element on the conducive film;
(h) heating and pressing the semiconductor element and the conductive film, thereby: contacting the linear conductors and the connecting terminals; bonding the linear conductors and the connecting terminals via the coating material; and curing the thermosetting resin layer.
